(19) United States
(12) Patent Application Publication
(10) Pub. No.: US 2005/0258502 A1
(43) Pub. Date: Nov. 24, 2005

(54) Chip package, image sensor module including chip package, and manufacturing method thereof

(76) Inventors: Yung-Cheol Kong, Chungcheongnam-do (KR); Jae-Cheon Doh, Chungcheongnam-do (KR); Byoung-Rim Seo, Seoul (KR); Seok-Won Lee, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/130,586

(22) Filed: May 16, 2005

(30) Foreign Application Priority Data
May 20, 2004 (KR) 2004-0035863

(51) Int. Cl. H01L 31/0203

(52) U.S. Cl. 257/433

(57) ABSTRACT

A chip package, an image sensor module including the same and a manufacturing method thereof. The chip package includes an image sensor chip having a plurality of bonding pads, a packaging substrate having a plurality of connection pads, an adhesive insulator, a plurality of conductive fillers, and a sealing insulator. The packaging substrate is mounted on the image sensor chip through the adhesive insulator, so that a light receiving area of the image sensor chip and an opening of the packaging substrate are vertically aligned. A plurality of through holes are formed to penetrate from portions of the connection pads to the packaging substrate. The through holes may be filled with the conductive fillers that are electrically connected between the bonding pads and the connection pads. The sealing insulator may protect the connective fillers.

### BACKGROUND OF THE INVENTION

This application claims the priority of Korean Patent Application No. 2004-35863, filed on May 20, 2004, in the Korean Intellectual Property Office, the disclosure of which is incorporated herein in its entirety by reference.

1. Field of the Invention

The present invention relates to a chip package and a method of manufacturing the same, and more particularly, to a chip package for an image sensor module and a method of manufacturing the same.

2. Description of the Related Art

An image sensor is a semiconductor device which converts optical information into an electrical signal. The image sensor includes a charge coupled device (CCD) and a complementary metal oxide semiconductor (CMOS). Such an image sensor is widely used in cameras, camcorders, personal computer (PC) cameras, surveillance cameras, and so on. As demands on mobile equipment with a built-in image sensor, such as camera phones, are explosively increasing, small-sized and thin image sensors are required. To manufacture small-sized and thin image sensors, it is necessary to manufacture a small-sized and thin package for an image sensor module.

In a conventional package for an image sensor module, a chip is mounted on a printed circuit board (PCB) or lead frame, and a bonding pad of the chip is electrically connected to a connection pad of the board using wire bonding. However, a package method using the wire bonding prevents the making of the package thinly due to a loop height of a wire.

One method proposed to solve the problem of the wire bonding is disclosed in U.S. Patent Application Publication No. 20030080434, published on May 1, 2003. In this patent application, a through hole exposing a bonding pad is formed at an image sensor chip and is filled with an electrically conductive material, so that the bonding pad is electrically connected with a connection pad. However, this patent application has a drawback in that a process of forming the through hole within a semiconductor chip is required. Also, if the through hole is formed, any active or passive devices cannot be formed below the bonding pad. Thus, in order to re-align the position of the bonding pad, an additional interconnection and process may be required, or a size of the image sensor chip will be relatively large.

Another method for providing a small-sized and thin package for an image sensor module is a flip chip package. Also, a thinner package can be manufactured using a chip on film (COF) technology that packages an image sensor on a flexible printed circuit (FPC), instead of a chip on board (COB) technology that packages an image sensor chip on a PCB.

FIG. 1A is a schematic cross-sectional view of a conventional image sensor module including a flip chip package. FIG. 1B is a partial enlarged view of a portion indicated by a dotted circle of FIG. 1A.

Referring to FIGS. 1A and 1B, an image sensor module 100 includes a housing 110 and a package 120 attached to the housing 110. The housing 110 has an opening that exposes an upper portion of an image sensor chip 121, that is, a light receiving area. The housing 110 may include various lenses and lens fixing units. The package 120 for the image sensor module includes an FPC substrate 123, an image sensor chip 121, a bump 125, an anisotropic conductive paste (ACP) or anisotropic conductive film (ACF) 126, and a sealing resin 127.

An opening exposing the light receiving area of the image sensor chip 121 is formed on the central portion of the FPC substrate 123. A plurality of connection pads 124 are formed around the opening on a bottom of the FPC substrate 123, that is, a side opposite to a side to which the housing 110 is attached. The ACF 126 may be attached to the connection pad 124 of the FPC substrate 123 in a band shape having a predetermined width, or the ACP 126 may be deposited thereon.

The light receiving area is formed on the central portion of the image sensor chip 121. A plurality of bonding pads 122 are formed on an edge portion of a coplanar surface of the light receiving area. The bonding pads 122 are aligned facing the connection pads 124. Au bump 125 is formed on the bonding pads 122, so that the bonding pads 122 can be easily connected with the connection pads 124. In the ACF 126, conduction balls disposed between the Au bump 125 and the connection pads 124 are aligned in one direction, so that they allow an electric current to flow through the Au bump 125 and the connection pads 124. However, conduction balls disposed at the remaining portion are freely dispersed, so that they do not allow an electric current to flow through the Au bump 125 and the connection pads 124.

The sealing resin 127 is formed around the Au bump 125. The sealing resin 127 protects the Au bump 125 and a contact surface between the Au bump 125 and the ACF 126 from moisture and impurities.

A method of manufacturing the image sensor module 100 shown in FIGS. 1A and 1B will now be described. First, the Au bump 125 is formed on the bonding pad 122 of a wafer-level image sensor chip 121 in which a chip fabrication process is completed. A sawing process is performed on the wafer to separate the image sensor chips 121. Then, the ACF 126 is aligned and attached to the FCB substrate 123 where the connection pad 124 is formed. Alternatively, the ACP 126 may be deposited precisely. One of the separated image sensor chips 121 is mounted on the FCB substrate 123. At this time, the Au bump on the image sensor chip 121 and the connection pad 124 must be correctly aligned. A predetermined heat and pressure are applied to attach the image sensor chip 121 to the ACF 126, and the Au bump 125 and the connection pad 124 are electrically interconnected due to the conductive balls of the ACF 126. Then, an end filling process is performed to form the sealing resin 127 around the Au bump 125 using an epoxy resin or the like. The housing 110 is attached to the edges of the FCB substrate 23. In this manner, the image sensor module 100 shown in FIG. 1A is completed.

However, the conventional image sensor module 100 has the following disadvantages.

First, since the ACF or ACP is expensive, a manufacturing cost is increased. Also, the conductive balls inside the ACF and the like must physically make contact with the bump and the connection pad. However, since the ACF and the like are very sensitive to thermal compression conditions, a margin of a thermal compression process is not large.

Second, a process of attaching the ACF to the FPC substrate or a process of depositing the ACP is very difficult. A resin constituting the ACF has a relatively large thermal expansion coefficient. Thus, there is a strong probability that the resin will be expanded in a thermal compression process and flow into the light receiving area. Therefore, a control process is required to control the inflow of the resin into the light receiving area in the thermal compression process. Also, the ACF and the like must be correctly aligned and attached. When the image sensor chip is mounted on the FCB substrate, the FCB substrate, the ACF and the image sensor chip must be correctly aligned.

Third, even though the sealing resin is formed to protect the Au bump and its connecting portion, protection of the Au bump is limited. The reason is that the Au bump and the conductive balls connecting the bonding pad and the connection pad are exposed to an outside of the housing. Accordingly, when the conventional image sensor module is used for a long period of time, its reliability is inevitably degraded.

### SUMMARY OF THE INVENTION

The invention provides a flip chip package and a manufacturing method thereof, capable of simplifying a manufacturing process, reducing a manufacturing cost and providing a large margin in an alignment of an image sensor chip because an ACF or ACP is not used.

Also, the invention provides an image sensor module including the flip chip package and a manufacturing method thereof, capable of preventing its reliability from being degraded even when it is used for a long time.

According to an aspect of the invention, an Au bump as well as an ACF or ACP is not used for an electrical connection between a packaging substrate and an image sensor chip. Instead, a packaging substrate having through holes is used. The through holes penetrate the packaging substrate through a bonding pad surface. That is, when the packaging substrate and the image sensor chip are aligned, the packaging substrate and the image sensor chip are electrically interconnected by directly forming an Au bump or depositing a conductive adhesive through the through holes.

In one embodiment, a chip package comprises an image sensor chip having a light receiving area formed at an upper portion and a plurality of bonding pads formed at a periphery of the light receiving area; a packaging substrate having an opening extending therethrough, the opening configured to expose the light receiving area, the packaging substrate mounted on the image sensor chip, the light receiving area and the opening being vertically aligned, the packaging substrate having a plurality of connection pads formed on an upper surface thereof, the plurality of connection pads being vertically aligned with the plurality of bonding pads, the plurality of connection pads including a plurality of through holes configured to extend through the plurality of connection pads and the packaging substrate, the image sensor chip being attached to a bottom surface of the packaging substrate, wherein the plurality of bonding pads and the plurality of connection pads are electrically interconnected through the plurality of through holes.

According to another embodiment of the invention, a flip chip package includes an image sensor chip, a packaging substrate, a plurality of connection pads, an adhesive insulator, a plurality of conductive fillers, and a sealing insulator. The image sensor chip includes a light receiving area formed at an upper portion and a plurality of bonding pads formed at a periphery of the light receiving area. The packaging substrate includes an opening exposing the light receiving area and it is mounted on the image sensor chip so that the light receiving area and the opening are vertically aligned. The plurality of connection pads are formed on an upper surface of the packaging substrate so that the plurality of connection pads are arranged with the plurality of bonding pads. The connection pads include a plurality of through holes penetrating from portions of the connection pads to the packaging substrate. The adhesive insulator encloses a periphery of the image sensor chip so that the image sensor chip is attached to a bottom surface of the packaging substrate. The plurality of conductive fillers fill the plurality of through holes and electrically interconnect the plurality of bonding pads and the plurality of connection pads. The sealing insulator encloses the plurality of conductive fillers to protect the conductive fillers.

The packaging substrate may be a FPC (flexible printed circuit) substrate. The through hole may be formed in a circular, rectangular or crisscross shape.

The conductive filler and the sealing insulator may be formed of an Au stud or a conductive adhesive. The adhesive insulator may be formed of an epoxy resin.

The flip chip package may further include: a plurality of wires electrically connected to the plurality of connection pads; and a connector having one end portion connected to the packaging substrate.

According to yet another embodiment of the invention, an image sensor module includes an image sensor chip, a packaging substrate, a plurality of connection pads, an adhesive insulator, a plurality of conductive fillers, a sealing insulator, a connector and a housing. The image sensor chip includes a light receiving area formed at an upper portion and a plurality of bonding pads formed at a periphery of the light receiving area. The packaging substrate includes an opening exposing the light receiving area and it is mounted on the image sensor chip so that the light receiving area and the opening are correctly aligned. The plurality of connection pads are formed on an upper surface of the packaging substrate so that the plurality of connection pads are aligned with the plurality of bonding pads. The connection pads include a plurality of through holes that penetrate from portions of the connection pads to the packaging substrate. The adhesive insulator encloses a periphery of the image sensor chip so that the image sensor chip is attached to a bottom surface of the packaging substrate. The plurality of conductive fillers fill the plurality of through holes and electrically interconnect the plurality of bonding pads and the plurality of connection pads. The sealing insulator encloses the plurality of conductive fillers so as to protect the conductive fillers. The connector has one end portion connected to the packaging substrate. The housing is included in the plurality of conductive fillers and is attached to the packaging substrate to expose the light receiving area.

The image sensor module may be mounted on a camera phone and the image sensor chip may be a CMOS image sensor device.

According to yet another aspect of the invention, a method of manufacturing a flip chip package includes: preparing a packaging substrate including an opening formed at a central portion and a plurality of connection pads formed at a periphery of the opening; forming a plurality of through holes that penetrate from portions of the connection pads to the packaging substrate; aligning and attaching an image sensor chip on a bottom surface of the packaging substrate, so that the light receiving area is exposed through the opening and the bonding pads are exposed through the through holes; depositing a conductive filler inside the through holes and on the connection pads so as to electrically interconnect the connection pads and the bonding pads; and sealing the conductive filler using an insulator.

The through holes may be formed using a laser. The aligning and attaching of the image sensor chip may include: preparing a wafer on which a plurality of image sensor chips are arrayed; separating the plurality of image sensor chips by sawing the wafer; aligning the separated image sensor chip on a bottom surface of the packing substrate; and attaching the aligned image sensor chips to the packaging substrate.

The attaching of the image sensor chip may be performed using an end filling process of depositing a periphery of the image sensor chip with an epoxy resin. The depositing of the conductive filler may be performed using a bump bonder or a dispenser.

According to still another aspect of the invention, a method of manufacturing an image sensor module includes: preparing a packaging substrate including an opening formed at a central portion and a plurality of connection pads formed at a periphery of the opening; forming a plurality of through holes penetrating from portions of the connection pads to the packaging substrate; aligning and attaching an image sensor chip on a bottom surface of the packaging substrate, such that the light receiving area is exposed through the opening and the bonding pads are exposed through the through holes; depositing a conductive filler inside the through holes and on the connection pads to electrically interconnect the connection pads and the bonding pads; and sealing the conductive filler using an insulator; and attaching a housing to an upper surface of the packaging substrate to expose the light receiving area, the plurality of conductive fillers being contained in the housing.

### BRIEF DESCRIPTION OF THE DRAWINGS

The above and other features and advantages of the present invention will become more apparent by describing in detail exemplary embodiments thereof with reference to the attached drawings in which:

FIG. 1A is a schematic cross-sectional view illustrating a conventional image sensor and an image sensor module including the same;

FIG. 1B is an enlarged view of a portion indicated by a dotted circle of FIG. 1A;

FIG. 2 is a flowchart illustrating a method of manufacturing an image sensor module according to an embodiment of the present invention;

FIG. 3A is a schematic plan view of a FPC substrate used to manufacture a flip chip package according to an embodiment of the present invention;

FIG. 3B is an enlarged view of a portion A shown in FIG. 3A;

FIG. 3C is a cross-sectional view taken along line XX′of FIG. 3A;

FIGS. 4A and 4B are a plan view and a cross-sectional view of an image sensor chip aligned on a rear side of a FPC substrate, respectively;

FIG. 5 is a plan view illustrating an end filing process;

FIGS. 6A and 6B are a cross-sectional view and a plan view of a conductive filler deposited into a through hole, respectively;

FIGS. 7A and 7B are a plan view and a cross-sectional view illustrating a process of depositing a sealing insulator; and

FIG. 8 is a cross-sectional view of an image sensor module including a flip chip package according to an embodiment of the present invention.

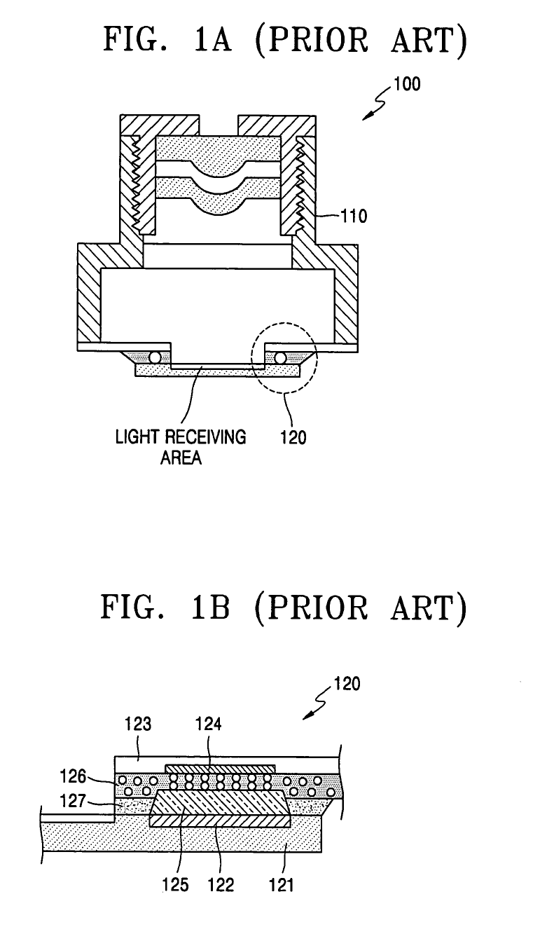

### DETAILED DESCRIPTION OF THE PREFERRED EMBODIMENTS

The invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. Like reference numerals in the drawings denote like elements.

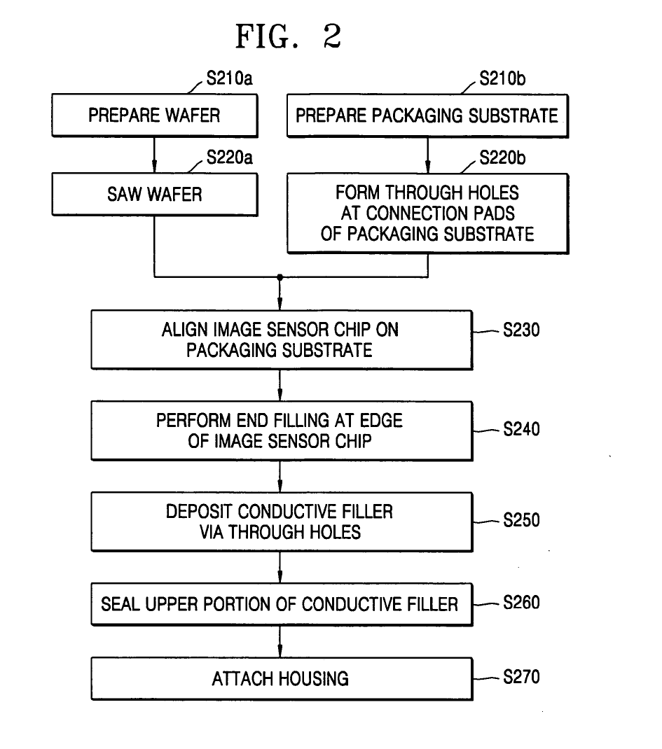

FIG. 2 is a flowchart illustrating a method of manufacturing an image sensor module according to a preferred embodiment of the invention. The method of the invention includes a method of manufacturing a flip chip package for an image sensor module chip provided inside the image sensor module.

Referring to FIG. 2, a wafer on which a plurality of image sensor chips are arranged is provided (S210a). A wafer sawing, that is, dicing, is performed to singulate (separate) the plurality of image sensor chips (220a) without forming a gold (Au) bump. As a result, an image sensor chip to be mounted on the flip chip package is prepared.

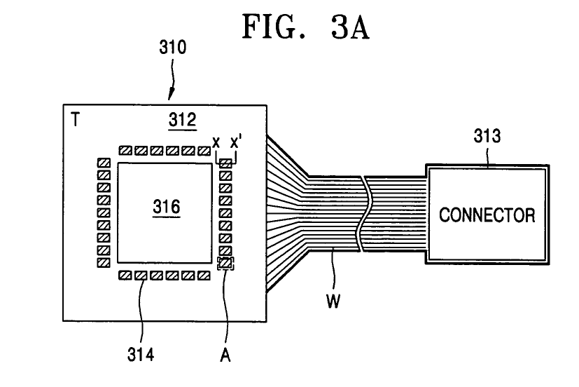

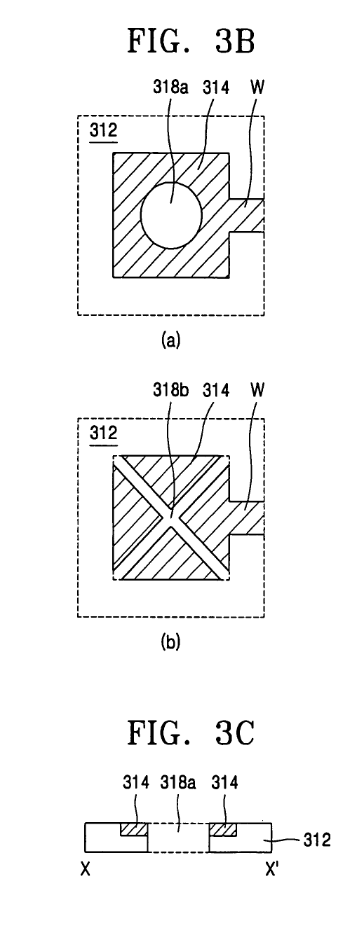

Apart from the preparation of the chip, a packaging substrate on which a plurality of through holes are formed is provided. First, the packaging substrate is prepared (S210b). The packaging substrate may be a PCB or FCB substrate. The FCB substrate is more preferred for manufacturing a thinner package. One example of the FCB is illustrated in FIG. 3.

Referring to FIG. 3A, an FPC substrate 310 and a connector 313 connected thereto are shown. A plurality of connection pads 314 of the FPC substrate 310 are electrically connected with the connector 313 through wires W. The FPC substrate 310 and the connector 313 are mounted on an electronic device such as a camera phone. The connector 313 may be structured to be mounted directly onto a system board (not shown).

Still referring to FIG. 3A, the FPC substrate 310 may be formed of a polyimide film 312. An opening 316 is formed at a central portion of the FPC substrate 310. The opening 316 exposes a light receiving area of the image sensor chip. The plurality of connection pads 314 and a plurality of wires (not shown) are formed on the polyimide film 312 adjacent to the opening 316. The plurality of connection pads 314 and the wires may be formed of a metal such as copper. In FIG. 3A, a reference symbol “T” represents an upper surface of the FPC substrate 310.

Next, through holes are formed in the packaging substrate 310 (S220b). FIGS. 3B and 3C are respectively a plan view and a cross-sectional view of the through holes 318a and 318b formed in the packaging substrate 310. FIG. 3B is an enlarged plan view of a portion A shown in FIG. 3A, and FIG. 3C is a cross-sectional view taken along line XX′ of FIG. 3A.

Referring to FIGS. 3B and 3C, the through holes 318a and 318b penetrate the packaging substrate 310 vertically at positions where the connection pads 314 are formed. If the packaging substrate 310 is the FPC substrate, the through holes 318a and 318b can be easily formed using conventional techniques such as a laser drilling technique.

As shown in FIG. 3B, the through holes 318a and 318b may be formed in a circular or crisscross shape. Also, the through holes 318 may be formed in a rectangular shape. Referring again to FIG. 2, the image sensor chip 320 prepared in the operation S220 is aligned on the packaging substrate 310 having the through hole 318a or 318b (S230) defined therein.

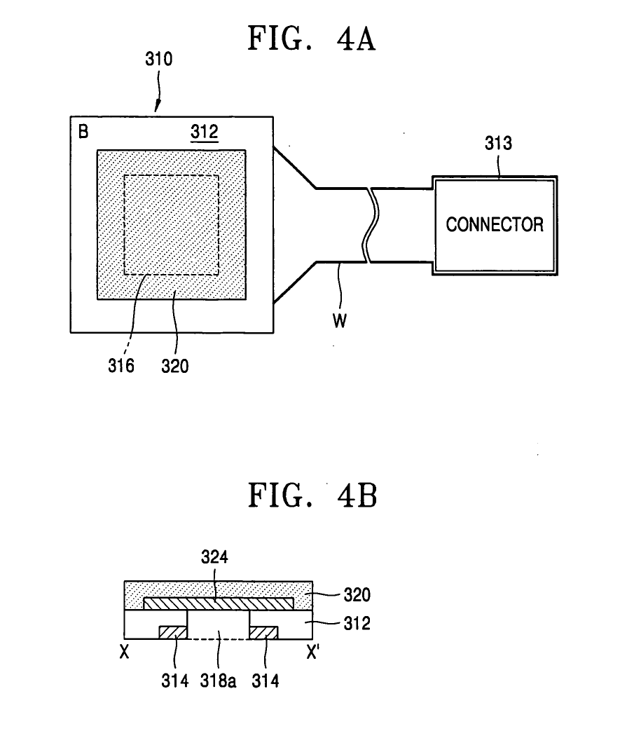

In FIGS. 4A and 4B, the aligned image sensor chip 320 is shown, and FIG. 4B is a cross-sectional view taken along line XX′ of FIG. 3A. Since the image sensor chip 320 is mounted on a bottom surface B of the packaging substrate 310, the packaging substrate 310 is turned over before the image sensor chip 320 is aligned.

Referring to FIGS. 4A and 4B, the image sensor chip 320 is aligned so that the light receiving area can be exposed through the opening 316 of the packaging substrate 310. The bonding pads 324 of the image sensor chip and the connection pads 314 of the packaging substrate 310 are perpendicularly aligned. As a result, the bonding pads 324 are exposed by the through holes 318a. In this embodiment, before the package manufacturing process is finished, the alignment of the connection pads 314 and the bonding pads 324 can be inspected by checking whether the bonding pads 324 are exposed by the through holes 318a.

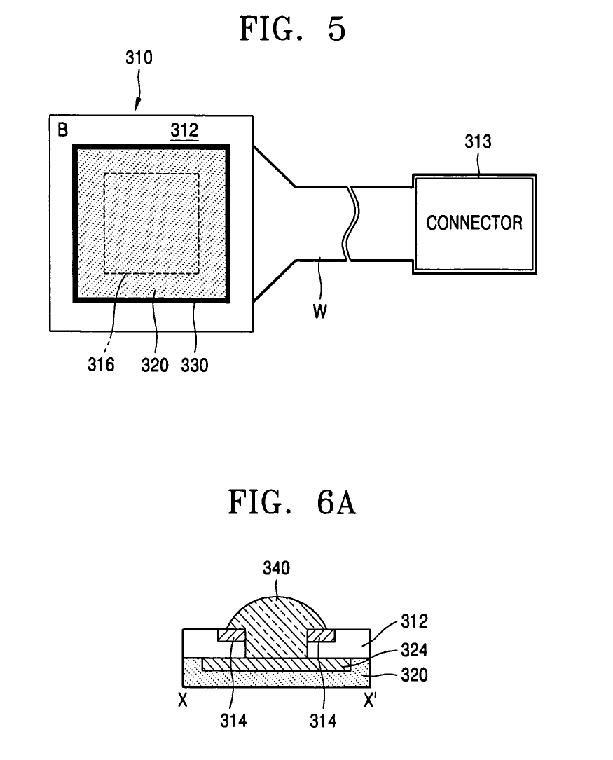

Then, the image sensor chip 320 is attached to the packaging substrate 310 (S240). The aligned image sensor chip 320 attached to the packaging substrate 310 is illustrated in FIG. 5.

Referring to FIG. 5, the attaching process may use an end filling process of depositing an adhesive insulator 330 on an end portion of the image sensor chip 320. The adhesive insulator 330 may be formed of a suitable insulative adhesive material such as, for example, an epoxy resin. The epoxy resin can be deposited on the end portion of the image sensor using a dispenser or screen printer.

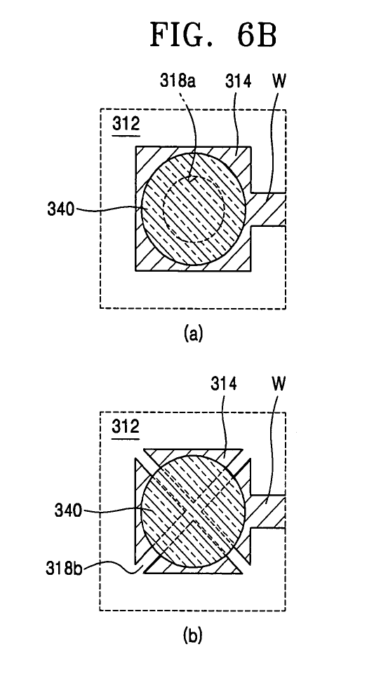

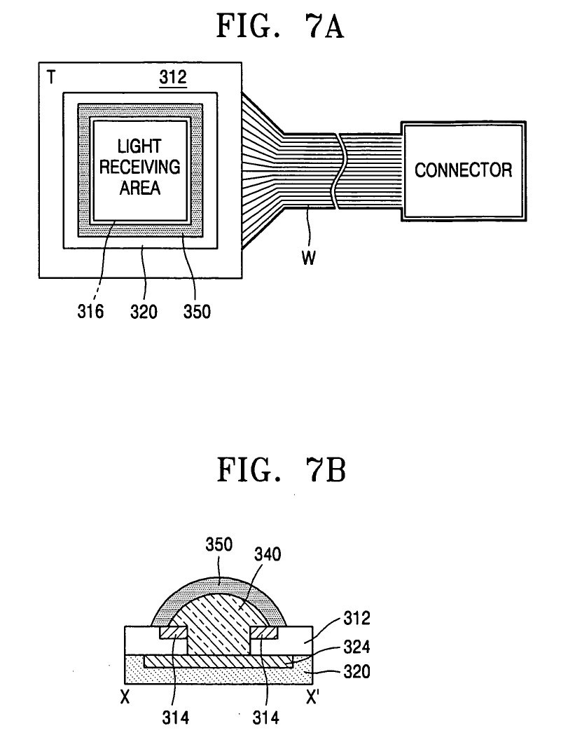

Then, the plurality of connection pads 314 and the bonding pads 324 are electrically connected to each other (S250). For this purpose, the packaging substrate 310 is turned over, so that the surface on which the connection pads 314 of the packaging substrate 310 are formed faces upwardly. In order to electrically interconnect the connection pads 314 and the bonding pads 324, the through holes 318a or 318b are filled with a conductive filler 340. FIGS. 6A and 6B are respectively a cross-sectional view and a plan view of the portion filled with the conductive filler 340.

Referring to FIGS. 6A and 6B, the conductive filler 340 fills the insides of the through holes 318a or 318b and is in contact with the bonding pads 324. Since the conductive filler 340 is also formed on the connection pads 314, the electrical connection can be achieved. The conductive filler 340 reinforces the adhesion between the packaging substrate 310 and the image sensor chip 320.

There is no special limitation on a method of forming the conductive filler 340. For example, the conductive filler 340 can be formed using a conventional apparatus and method of manufacturing an Au bump. That is, the through holes 318a or 318b can be filled with a conductive metal, such as Au, using a bump bonder. Alternatively, the conductive filler 340 can be formed by depositing a conductive adhesive on the through holes 318a or 318b using a dispenser.

FIG. 6B illustrates the state when the through holes 318a and 318b are filled with the conductive filler 340 depending on their shapes. In particular, as shown in FIG. 6B(a), when the through holes 318a are formed in a circular or rectangular shape, the conductive filler 340 is formed inside the through holes 318a and on the connection pads 314. On the other hand, as shown in FIG. 6B(b), when the through holes 318b are formed in a crisscross shape, the through holes 318b are filled with the conductive filler 340 which presses on a portion of the connection pad 314. As a result, the connection pads 314 are bent toward the bottom side of the FPC substrate 310, thereby improving the electrical connection between the connection pads 314 and the bonding pads 324.

Referring again to FIG. 2, a sealing insulator 350 (FIG. 7B) is deposited to protect a portion that is electrically connected by the conductive filler 340 (S260).

FIGS. 7A and 7B are a respectively plan view and a partial cross-sectional view of the flip chip package on which the sealing insulator 350 is deposited. Referring to FIGS. 7A and 7B, in order to completely cover the conductive filler 340, the sealing insulator 350 is deposited on and around the conductive filler 340. The sealing insulator 350 protects the conductive filler 340, thereby improving the reliability and maintaining the adhesive force. The sealing insulator 350 may be formed of a suitable insulator such as an epoxy resin. Like the adhesive insulator 330, the sealing insulator 350 may be linearly formed using a dispenser or a screen printer.

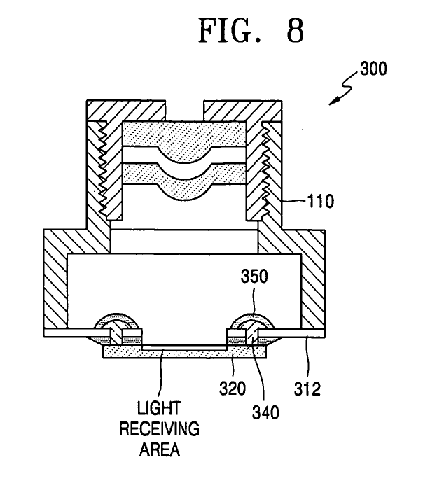

Through the above processes, the flip chip package including the image sensor chip 320 is completed. A schematic cross-sectional view of the completed flip chip package is illustrated in FIG. 8, and a plan view and a partial enlarged view thereof are illustrated in FIGS. 7A and 7B. Referring to FIGS. 7A, 7B and 8, the flip chip package includes the image sensor chip 320 on which the plurality of bonding pads 324 are formed, the packaging substrate 310 on which the plurality of connection pads 314 (FIG. 3A) are formed, the adhesive insulator 330, the plurality of conductive filler 340, and the sealing insulator 350.

In the image sensor chip 320, the light receiving area is formed at an upper portion, e.g., an upper central portion, and the bonding pads are formed around the light receiving area. The packaging substrate 310 includes the opening defined therein to expose the light receiving area. The light receiving area and the opening 316 are vertically aligned. The packing substrate 310 is disposed on the upper surface of the image sensor chip 320, so that the light receiving area can be exposed through the opening 316. The adhesive insulator 330 enclosing the periphery of the image sensor chip 320 is formed so that the image sensor chip 320 can be attached to the bottom surface of the packaging substrate 310.

The plurality of connection pads 314 and the plurality of bonding pads 324 may be vertically aligned in a one-to-one correspondence. The plurality of through holes 318a or 318b penetrating the packaging substrate 310 from their portions, e.g., central portions, are formed on the packaging substrate 310. The through holes 318a or 318b are filled with the conductive fillers 340 which electrically interconnect the respective bonding pads 324 and the respective connection pads 314. In order to protect the plurality of conductive fillers 340, the sealing insulator 350 encloses the plurality of conductive filler 340.

A method of manufacturing the image sensor module 300 will now be described. Referring to FIGS. 2 and 8, the housing 110 is attached to the upper surface of the packaging substrate 310 of the completed flip chip package (S270). The attaching process uses a general adhesive. FIG. 8 is a cross-sectional view of the image sensor module 300 to which the housing 110 is attached according to an embodiment of the invention. There is no special limitation on kinds and structures of the housing 110 which can be applied to the invention. As described above, one or more lenses are provided at the housing 110. Generally, a processing of assembling the lenses is performed after attaching the housing 110 to the packaging substrate 310.

Referring again to FIGS. 7A through 8, in the image sensor module 300, the connection pads 314, the bonding pads 324, and the conductive filler 340 electrically interconnecting the pads 314 and 324 are exposed inside the housing 110. That is, the electrically interconnected portion between the packaging substrate 310 and the image sensor chip 320 are not exposed to the atmosphere. As a result, the reliability of image sensor module 300 is improved

According to the invention, the Au bump is not formed on the bonding pad. Therefore, the manufacturing method of the flip chip package can be simplified. Also, because the expensive ACF or ACP is not used, the manufacturing cost can be reduced and subsequent processes can be simplified. Also, the process of precisely aligning the ACF or depositing the ACP can be made easier. Further, there is no burden of correctly aligning the image sensor chip. Whether the connection pads and the bonding pads are correctly aligned can be checked through the through holes. Thus, the process failure due to the misalignment can be checked before the flip chip package is completed.

Also, according to the image sensor module of the invention, the elements, such as the connection pads, the bonding pads and the conductive fillers, for electrically interconnecting the packaging substrate and the image sensor chip are disposed inside the housing. Therefore, it is possible to prevent the reliability of the image sensor module from being degraded due to the external exposure.

While the invention has been particularly shown and described with reference to exemplary embodiments thereof, it will be understood by those of ordinary skill in the art that various changes in form and details may be made therein without departing from the spirit and scope of the invention as defined by the following claims.

1. A chip package comprising:
an image sensor chip including a light receiving area formed at an upper portion thereof and a plurality of bonding pads formed at a periphery of the light receiving area;
a packaging substrate having an opening extending therethrough, the opening configured to expose the light receiving area, the packaging substrate mounted on the image sensor chip, the light receiving area and the opening being vertically aligned, the packaging substrate having a plurality of connection pads formed on an upper surface thereof, the plurality of connection pads being vertically aligned with the plurality of bonding pads, the plurality of connection pads including a plurality of through holes extending therethrough and through the packaging substrate, the image sensor chip being attached to a bottom surface of the packaging substrate,
wherein the plurality of bonding pads and the plurality of connection pads are electrically interconnected through the plurality of through holes.

2. The chip package of claim 1, further comprising an adhesive insulator enclosing a periphery of the image sensor chip to attach the image sensor chip to the bottom surface of the packaging substrate.

3. The chip package of claim 2, wherein the adhesive insulator is formed of an epoxy resin.

4. The chip package of claim 1, wherein the plurality of bonding pads and the plurality of connection pads are electrically connected to each other using a plurality of conductive fillers filling the through holes.

5. The chip package of claim 4, further comprising a sealing insulator enclosing the plurality of conductive fillers to protect the conductive fillers.

6. The chip package of claim 5, wherein the sealing insulator is formed of an epoxy resin.

7. The chip package of claim 4, wherein the plurality of conductive fillers are formed of an Au stud or a conductive adhesive.

8. The chip package of claim 1, wherein the packaging substrate is a FPC (flexible printed circuit) substrate.

9. The chip package of claim 1, wherein each of the plurality of through holes is formed in a circular, rectangular or crisscross shape.

10. The chip package of claim 1, further comprising:
a plurality of wires electrically connected to the plurality of connection pads; and
a connector having one end portion connected to the packaging substrate.

11. An image sensor module comprising:
an image sensor chip including a light receiving area formed at an upper portion thereof and a plurality of bonding pads formed at a periphery of the light receiving area;
a packaging substrate including an opening exposing the light receiving area, the packaging substrate being mounted on the image sensor chip so that the light receiving area and the opening are vertically aligned, the packaging substrate having a plurality of connection pads being formed on an upper surface thereof so that the plurality of connection pads are vertically aligned with the plurality of bonding pads, the plurality of connection pads including a plurality of through holes penetrating from portions of the plurality of connection pads to the packaging substrate, the image sensor chip being attached to a bottom surface of the packaging substrate;
a plurality of conductive fillers filling the plurality of through holes and electrically interconnecting the plurality of bonding pads and the plurality of connection pads; and
a housing enclosing the plurality of conductive fillers therein, the housing being attached to the packaging substrate to expose the light receiving area.

12. The image sensor module of claim 11, further comprising an adhesive insulator enclosing a periphery of the image sensor chip so that the image sensor chip is attached to the bottom surface of the packaging substrate.

13. The image sensor module of claim 11, further comprising a sealing insulator enclosing the plurality of conductive fillers to protect the conductive fillers;

14. The image sensor module of claim 11, wherein the packaging substrate is a FPC (flexible printed circuit) substrate.

15. The image sensor module of claim 11, wherein the through hole is formed in a circular, rectangular or crisscross shape.

16. The image sensor module of claim 11, wherein the plurality of conductive fillers is formed of an Au stud or a conductive adhesive.

17. The image sensor module of claim 11, wherein the image sensor module is mounted on a camera phone.

18. The image sensor module of claim 11, wherein the image sensor chip is a CMOS image sensor device.

19. A method of manufacturing a chip package, comprising:
providing a packaging substrate including an opening formed at a portion thereof and a plurality of connection pads formed at a periphery of the opening;
forming a plurality of through holes extending through portions of the connection pads and through the packaging substrate;
aligning and attaching an image sensor chip that includes a light receiving area and that includes a plurality of bonding pads on a bottom surface of the packaging substrate, so that the light receiving area is exposed through the opening and the plurality of bonding pads are exposed through the plurality of through holes; and
electrically interconnecting the plurality of connection pads and the plurality of bonding pads through the plurality of through holes.

20. The method of claim 19, wherein electrically interconnecting comprises depositing a conductive filler inside the plurality of through holes and on the plurality of connection pads.

21. The method of claim 20, further comprising sealing the conductive filler using an insulator.

22. The method of claim 20, wherein the depositing of the conductive filler is performed using a bump bonder or a dispenser.

23. The method of claim 19, wherein the packaging substrate is a FPC (flexible printed circuit) substrate.

24. The method of claim 19, wherein the plurality of through holes are formed using a laser drilling method.

25. The method of claim 19, wherein the aligning and attaching of the image sensor chip comprises:
providing a wafer on which a plurality of image sensor chips are arranged;
singulating the plurality of image sensor chips;
aligning the separated image sensor chip on a bottom surface of the packaging substrate; and
attaching the aligned image sensor chip to the packaging substrate.

26. The method of claim 25, wherein the attaching of the aligned image sensor chip is performed using an end filling process of depositing at a periphery of the image sensor chip with an epoxy resin.

27. A method of manufacturing an image sensor module, comprising:
providing a packaging substrate including an opening formed at a central portion and a plurality of connection pads formed at a periphery of the opening;
forming a plurality of through holes penetrating from portions of the plurality of connection pads to the packaging substrate;
aligning and attaching an image sensor chip that includes a light receiving area and that includes a plurality of bonding pads on a bottom surface of the packaging substrate, so that the light receiving area is exposed through the opening and the plurality of bonding pads are exposed through the plurality of through holes;
depositing a conductive filler inside the plurality of through holes and on the plurality of connection pads to electrically interconnect the plurality of connection pads and the plurality of bonding pads; and
sealing the conductive filler using an insulator; and
attaching a housing to an upper surface of the packaging substrate to expose the light receiving area, the plurality of conductive fillers being contained in the housing.
